(19) United States
(12) Patent Application Publication
(10) Pub. No.: US 2016/0316572 A1
(43) Pub. Date: Oct. 27, 2016

(54) METHOD FOR MOUNTING A COMPONENT ON A SUBSTRATE

(71) Applicant: HERAEUS DEUTSCHLAND GMBH & CO. KG, Hanau (DE)

(72) Inventors: Jens NACHREINER, Schlüchtern (DE); Joachim WIESE, Höchst/Odenwald (DE); Sebastian FRITZSCHE, Hanau (DE)

(21) Appl. No.: 15/105,378

(22) PCT Filed: Dec. 12, 2014
(86) PCT No.: PCT/EP2014/077559

§ 371 Date: Jun. 16, 2016

(30) Foreign Application Priority Data
Dec. 17, 2013 (EP) 13197640.9

(51) Int. Cl. H05K 3/34; B23K 35/362; B23K 35/26; B23K 35/36; B23K 1/00; B23K 35/02

(52) U.S. Cl. CPC H05K 3/3436; B23K 1/0016; B23K 35/025; B23K 35/262; B23K 35/3618; B23K 35/3615; B23K 35/362; H05K 3/3463; H05K 3/3489

(57) ABSTRACT

A method for mounting an electronic component on a substrate is provided. The method involves the use of a solder paste that includes a mixture of organic dicarboxylic acids. The thickness of the solder deposit is 25 to 200 μm.

### CROSS-REFERENCE TO RELATED APPLICATIONS

This application is a Section 371 of International Application No. PCT/EP2014/077559, filed Dec. 12, 2014, which was published in the German language on Jun. 25, 2015 under International Publication No. WO 2015/091260 A1 and the disclosure of which is incorporated herein by reference.

### BACKGROUND OF THE INVENTION

The present invention relates to a method for mounting an electronic component on a substrate through the use of a solder paste that comprises a mixture of organic dicarboxylic acids and in which the thickness of the solder deposit is 25 to 200 μm.

The main application of solder pastes, in particular of soft solder pastes, is in the production of electronic circuits such as, for example, in the semiconductor industry. In this context, electronic components are applied onto substrates such as, for example, printed circuit boards and are connected to same mechanically, electronically, and thermally by means of a solder paste. Accordingly, the existing requirements for a method of this type and the solder pastes used in it are manifold, especially taking into consideration an automated process. Usually, the surface of the substrate is provided with a solder paste by means of which the contact to the component is established. Heating of the solder paste leads to the mechanical contact becoming firmer. Aside from mechanical bonding, the solder paste can also serve to establish an electrical contact between component and substrate and/or to dissipate the heat generated during operation of the component.

WO 02/20211 A1 describes a soldering agent for use in diffusion soldering processes that comprises a mixture of at least partially metallized grains made of a higher melting metal and a solder metal, which differ in their melting temperatures.

DE 195 11 392 A1 describes a method and a device for applying soldering humps by means of energy-rich radiation, in particular laser radiation.

U.S. Pat. No. 5,672,542 relates to a method and a process for the application of electrically conductive substances onto a substrate by means of soldering balls, whereby the soldering balls have a distance of maximally 400 μm from each other.

A special challenge of these methods are electronic components, which comprise, aside from electrical connecting sites, thermal connecting sites on the underside as well, such as, for example, QFP components (quad flat package) comprising electrical connecting sites in the form of so-called legs that are mounted on the sides of the component and by means of which the electrical contact between component and substrate is established, and comprise a thermal connecting site on the underside that serves to dissipate the heat of the component generated during its operation. The contacting of the connecting sites to the substrate takes place each with different solder pastes, one for thermal connection and one for electrical connection. In the course of this process, the introduced solder deposit of the thermal connecting sites might spread upon heating. In this context, solder powder particles are driven out in the direction of the electrical contacting sites, usually in the form of so-called soldering balls, and might cause short-circuiting at these sites. This might be a problem, especially if the predetermined distance between component and substrate, for example via the electrical connecting sites, requires the use of a correspondingly large amount of solder paste to effect the mutual contacting.

### BRIEF SUMMARY OF THE INVENTION

It is therefore an objective of the present invention to provide a method for mounting components, in particular components with electrical and thermal connecting sites, on substrates, in which spreading of the solder paste and the generation of undesired solder balls is prevented, such that the occurrence of electrical short-circuits is prevented or at least minimized without adversely affecting the thermal and mechanical connection of the component to the substrate.

### BRIEF DESCRIPTION OF THE SEVERAL VIEWS OF THE DRAWINGS

The foregoing summary, as well as the following detailed description of the present invention, will be better understood when read in conjunction with the appended drawings. For the purpose of illustrating the present invention, there are shown in the drawings embodiments which are presently preferred. It should be understood, however, that the present invention is not limited to the precise arrangements and instrumentalities shown.

In the drawings:

FIG. 1 illustrates an experimental setup in which the solder paste according to the present invention has been applied to the thermal connecting site of a QFP component and covered with a glass plate;

FIG. 2 illustrates the results of an Anti-Capillary (AC) test for a solder deposit thickness of 100 μm;

FIG. 3 illustrates the results of an AC test for a solder deposit thickness of 120 μm;

FIG. 4 illustrates the results of an AC test for a solder deposit thickness of 160 μm; and

FIG. 5 illustrates the results of an AC test for a solder deposit thickness outside the range of 25 to 200 μm.

### DETAILED DESCRIPTION OF THE INVENTION

In the scope of the present invention, the term “spreading” shall be understood to mean a spreading of the solder paste for thermal connection of component and substrate beyond the limits of the thermal connecting site of the component and/or substrate and the generation of undesired solder balls when the solder paste is heated under process conditions such that the solder paste contacts the electrical connecting sites of the component and short-circuits thus occur.

It has been discovered, surprisingly, that the use of a solder paste comprising a solder and a flux, in particular a flux comprising a mixture of two different dicarboxylic acids, allows the spreading of the solder paste and the generation of undesired solder balls and thus short-circuiting at the electrical connecting sites of the component to be prevented. Moreover, it has also been discovered that the thickness of the solder deposit between the component and substrate is crucial for controlling the spreading.

Accordingly, one embodiment of the present invention is a method for mounting a component on a substrate that comprises the following steps:

i) Providing a component having a first surface, whereby the component is provided with electrical and thermal connecting sites;

ii) providing a substrate having a second surface that is provided with a solder deposit;

iii) mechanical contacting of the first surface of the component to the second surface of the substrate by means of the solder deposit, whereby the thickness of the solder deposit is 25 to 200 μm; and

iv) heating the solder deposit beyond the liquidus temperature of the solder, whereby the solder deposit is formed by a solder paste comprising a solder and a flux, whereby the flux comprises a dicarboxylic acid A and a dicarboxylic acid B that differ from each other.

The solder deposit, which shall be described in more detail in the following, is an essential component of the method.

### a) Solder Deposit

The solder deposit is formed by a solder paste that is composed of a flux and a solder. The individual components of the solder paste are specified in more detail in the following.

Flux:

The flux is an important component of the solder paste and determines mainly its rheological properties. It has been discovered, surprisingly, that short-circuiting during the mounting of a component on a substrate can be prevented if a flux is used that comprises a mixture of two different dicarboxylic acids. It has been discovered that the use of a solder paste comprising the flux allows a stable mechanical and thermal connection between the component and substrate to be established without electrical short-circuiting, and it has been discovered that the solder paste also comprises good processability and good wetting properties. In particular, in concert with the solder paste having a defined deposit thickness in the range of 25 to 200 μm, excellent properties are evident.

Particularly good results were obtained with dicarboxylic acids that comprised a certain number of carbon atoms.

Accordingly, an embodiment of the method according to the present invention, in which dicarboxylic acid A comprises 5 or more carbon atoms, preferably 6 to 8 carbon atoms, and in particular 6 carbon atoms, is preferred. In a particularly preferred embodiment, dicarboxylic acid A is adipic acid.

Moreover, it has proven to be advantageous to use, as further component, a dicarboxylic acid B that comprises fewer carbon atoms than dicarboxylic acid A.

Accordingly, an embodiment, in which dicarboxylic acid B comprises 4 or fewer carbon atoms, in particular 2 carbon atoms, is preferred. An embodiment, in which dicarboxylic acid B is oxalic acid, is particularly preferred.

It has also been discovered, surprisingly, that the advantageous effects are present especially when dicarboxylic acid A and dicarboxylic acid B are present at a certain weight ratio with respect to each other.

In a preferred embodiment, the weight ratio of dicarboxylic acid A to dicarboxylic acid B therefore is 30:1 to 5:1, preferably 25:1 to 7:1, in particular 20:1 to 10:1.

In a particularly preferred embodiment of the method according to the present invention, the solder paste comprises the following components:

a) 5 to 15% by weight of a flux and

b) 85 to 95% by weight of a solder,

whereby the weight specifications each relate to the total weight of the solder paste and whereby the flux comprises:
i) 7 to 13% by weight dicarboxylic acid A, preferably adipic acid;
ii) 0.3 to 2.0% by weight dicarboxylic acid B, preferably oxalic acid; and
iii) an amine, preferably selected from amine component X and amine component Y, whereby amine component X is a diamine with tertiary amino groups and amine component Y is a diamine or polyamine, in which at least 2 of the amino groups are separated from each other by at least 3 carbon atoms and which comprises at least 4 carbon atoms, whereby the weight specifications of the dicarboxylic acids each relate to the total weight of the flux.

An embodiment, in which the flux comprises dicarboxylic acid A in an amount of 7 to 13% by weight, preferably 8 to 12% by weight, each relative to the total weight of the flux, is particularly preferred.

An embodiment, in which the flux contains dicarboxylic acid B in an amount of 0.3 to 2.0% by weight, preferably of 0.4 to 1.5% by weight, more preferably of 0.45 to 1.0% by weight, each relative to the total weight of the flux, is also preferred.

Amine components X and Y are illustrated in more detail in the following.

### Amine Component X

Amine component X is a diamine that comprises at least one tertiary amino group, preferably two tertiary amino groups.

A preferred embodiment has amine component X selected from the group consisting of 1,2-tetramethylethylenediamine, 1,2-tetraethylethylenediamine and 1,2-tetrapropylethylenediamine, for example 1,2-tetra-n-propylethylenediamine and 1,2-tetra-isopropylethylenediamine. Diamines, in which each tertiary amino group comprises two identical substituents, are particularly preferred.

In the scope of the present invention, a tertiary amine shall be understood to be an amine whose nitrogen atom bears three carbon-containing substituents.

### Amine Component Y

Amine component Y is a diamine or polyamine, in which at least 2 of the amino groups are separated from each other by at least 3 carbon atoms and which comprises at least 4 carbon atoms.

Amine component Y is a diamine, in which the two amino groups are separated from each other by at least 3 carbon atoms and which comprises at least 4 carbon atoms. Alternatively, amine component Y is a polyamine, in which at least 2 of the amino groups are separated from each other by at least 3 carbon atoms and which comprises at least 4 carbon atoms.

Moreover, it has been discovered, surprisingly, that the advantageous rheological properties of the solder paste can be improved even further if amine component Y comprises a primary amino group.

Accordingly, amine component Y comprises at least one primary amino group in a preferred embodiment of the present invention.

In a preferred embodiment, amine component Y is selected from the group consisting of N-coco-1,3-diaminopropane, 1,6-diaminohexane, 1,7-diaminoheptane, 1,8-diaminooctane, 1,9-diaminononane, and 1,10-diaminodecane.

In a further preferred embodiment, the amine to be used, i.e. amine component X or amine component Y, comprises no tertiary and/or quaternary carbon atoms.

In a further preferred embodiment, the amine comprises at least 6 carbon atoms. In this context, the carbon atoms can be present as a connecting chain between two amino groups or can be bound to the same as substituents of the nitrogen atoms.

In a preferred embodiment, the total amount of amine, i.e. amine component A and/or amine component B, in the flux is 2% by weight or less, preferably 1% by weight or less, for example 0.1% by weight to 2.0% by weight, each relative to the total weight of the flux.

The amount of amine in the flux is preferably selected appropriately such that good processability of the solder paste and good wettability of the surfaces of the component and substrate to be mounted are ensured.

Therefore, in a preferred embodiment, the flux comprises amine component X and/or amine component Y in an amount of 0.1 to 2.0% by weight, preferably of 0.4 to 1.0% by weight, each relative to the total weight of the flux.

In a further preferred embodiment, the flux further comprises monoamine. The monoamine is present in addition to amine component X and/or amine component Y.

Particularly good results can be obtained, especially with regard to the processability and the spreading behaviour of the solder paste, if the monoamine is a secondary and/or tertiary monoamine. Therefore, a preferred embodiment has the monoamine selected from the group consisting of secondary monoamine and tertiary monoamine as well as mixtures thereof. Particularly preferably, the monoamine is a tertiary monoamine. Preferably, the flux contains monoamine in an amount of 0.5 to 5.5% by weight, preferably of 1.0 to 5.0% by weight, each relative to the total weight of the flux.

It has proven to be particularly advantageous if the flux contains, aside from dicarboxylic acids A and B, further dicarboxylic acids that differ from dicarboxylic acids A and B.

Therefore, an embodiment, in which the flux comprises, in addition, dicarboxylic acids other than dicarboxylic acid A and dicarboxylic acid B in an amount of 0 to 2% by weight, preferably in an amount of 0.01 to 1.0% by weight, each relative to the total weight of the flux, is preferred.

Therefore, an embodiment, in which the total amount of all dicarboxylic acids in the flux is maximally 15% by weight, preferably 7 to 13% by weight, in particular 8 to 12% by weight, each relative to the total weight of the flux, is also preferred.

It has been discovered that the wetting properties and the processability as well as other properties of the solder paste can be improved by means of further additives.

Therefore, the flux of the solder paste for use in the method according to the present invention comprises further additives, preferably in an amount of 0.05 to 3.0% by weight, each relative to the total weight of the flux. These additives preferably are compounds improving the wetting properties of the solder paste such as, for example, ethoxylated amine resin, amine resin, methyl esters of resins, n-oleylsarcosine, oleylimidazoline, and mixtures thereof.

An embodiment is preferred, in which the flux further comprises, in addition, a solvent, in particular a solvent selected from the group consisting of the following, soluble at 25° C., dioles, alcohols, etheralcohols, and ketones, in particular trimethylpropanol, 1,2-octandiol, 1,8-octandiol, 2,5-dimethyl-2,5-hexandiol, iso-bornylcyclohexanone, glycol ether, 2-ethyl-1,3-hexandiol, n-decylalcohol, 2-methyl-2,4-pentandiol, terpineol, and isopropanol as well as mixtures thereof. In a further preferred embodiment, the glycol ether is selected from the group consisting of mono-, di-, tri-propyleneglycolmethylether, mono-, di-, tri-propyleneglycol-n-butylether, mono-, di-, tri-ethyleneglycol-n-butylether, ethyleneglycolmethylether, triethyleneglycolmethylether, diethyleneglycol-dibutylether, tetraethyleneglycoldimethylether, and diethyleneglycol-monohexylether as well as mixtures thereof.

Moreover, the flux can comprise a resin in order to impart on the solder paste the consistency required for the corresponding application. In a preferred embodiment, the flux contains, in addition, a resin, preferably a resin selected from the group consisting of colophony, tall oil, hydrogenated colophony, dimerised colophony, partially dimerised colophony, and mixtures thereof.

In a preferred embodiment, the resin is present in an amount of 35 to 50% by weight, preferably of 40 to 48% by weight, each relative to the total weight of the flux.

The results of the method according to the present invention can be improved even more if the flux comprises an activator, for example a halogen-containing compound, that activates the surfaces of the solder powder, component and substrate to be connected and thus provides for a better connection of the components.

Therefore, an embodiment, in which the flux contains, in addition, halogen-containing compounds selected from the group consisting of aniline hydrochloride, glutamic acid hydrochloride, diethanolamine hydrochloride, triethanolamine hydrobromide, triethanolamine hydrochloride, triethanolamine hydrobromide, and trans-2,3-dibromo-2-buten-1,4-diol as well as mixtures thereof, is preferred.

It has proven to be particularly advantageous that the amount of halogen-containing compounds in the flux does not exceed 5% by weight, relative to the total weight of the flux. Therefore, an embodiment of the solder paste according to the present invention, in which the flux comprises halogen-containing compounds in an amount of 0.1 to 3.0% by weight, preferably 0.5 to 2.0% by weight, each relative to the total weight of the flux, is preferred.

In an alternative preferred embodiment, the solder paste used in the method according to the present invention is essentially free of halogen-containing compounds. In the scope of the present invention, pastes shall be considered to be essentially free of halogen-containing compounds if they are pastes that comprise halogen-containing compounds in an amount of less than 0.1% by weight, preferably between 0 and 0.09% by weight, specifically less than 0.01% by weight or less than 0.005% by weight, each relative to the total weight of the flux.

The flux can contain, for example, thickening agents to improve the rheological properties and the wettability of the solder paste. In a preferred embodiment, the flux comprises, in addition, one or more thickening agents, preferably selected from the group consisting of ethylcellulose, hydrogenated castor oil, glycerol-tris-12-hydroxystearin, and modified glycerol-tris-12-hydroxystearin. Preferably, the flux contains thickening agent in an amount of 1.0 to 4.0% by weight, preferably of 1.7 to 3.0% by weight, each relative to the total weight of the flux.

The solder described in more detail in the following is another important component of the solder paste used in the method according to the present invention.

### Solder:

The solder and the flux, together, form the solder deposit by means of which the thermal bonding of the component to the substrate takes place. Since the heat generated during operation of the component is to be dissipated by means of the connection, it is desirable for the solder to have good thermal conductivity, if possible, in combination with limited electrical conductivity. These properties are evident especially in solders that comprise tin as their main component.

Accordingly, an embodiment, in which the solder is a tin-based solder, is preferred.

In the scope of the present invention, a tin-based solder is a solder that comprises at least 80% by weight, preferably at least 83% by weight, in particular between 85 and 90% by weight, tin, whereby the weight specifications each relate to the total amount of solder.

In a preferred embodiment, the solder can comprise further metals aside from tin, for example in order to adjust the liquidus temperature of the solder to an advantageous range for the respective application.

Therefore, an embodiment, in which the solder comprises silver in an amount of 0.1 to 8% by weight, preferably 0.2 to 6% by weight, each relative to the total weight of the solder, is preferred.

In a further preferred embodiment, the solder comprises copper in an amount of 0.1 to 1.5% by weight, preferably 0.2 to 1.0% by weight, each relative to the total weight of the solder.

An embodiment, in which the solder is free of lead, is also preferred.

The solder paste is well-suited in particular for use in the method according to the present invention, in which the solder is heated up to more than its liquidus temperature and thus provides for optimal connection between component and substrate. Accordingly, the liquidus temperature of the solder should not be too high for reasons of energy technology and taking into consideration the sensitive components and substrates.

Accordingly, an embodiment, in which the solder has a liquidus temperature in the range of 200 to 250° C., preferably in the range of 200 to 230° C., is preferred.

In a preferred embodiment, the solder is present as a powder, preferably having a weight-averaged particle size of 15 to 50 μm, preferably of 20 to 45 μm, determined in accordance with IPC-TM-650 2.2.14-2.2.14.2. In a preferred embodiment, 80 to 90% of the particles in the powder have a size in the range of 15 to 50 μm, preferably of 20 to 45 μm. In the scope of the present invention, particle size shall be understood to refer to the maximum linear extension of a particle.

In a further preferred embodiment, the solder paste comprises the solder in an amount of 80 to 97% by weight, preferably 83 to 95% by weight, in particular 85 to 93% by weight, each relative to the total weight of the solder paste.

### B) Method

In the following, the individual steps of the method according to the present invention are illustrated in more detail.

A component is provided in a first step of the method according to the present invention for mounting a component on a substrate. The method according to the present invention is well-suited especially for mounting components, which are provided with thermal and electrical connection sites, on substrates, whereby the contacting takes place by means of a first surface of the component and a second surface of the substrate by means of a solder deposit. Preferably, the first surface of the component comprises at least one metal selected from the group consisting of copper, silver, gold, nickel, aluminum, tin, palladium as well as alloys of two or more of the metals.

Preferably, the component comprises a square footprint. The size of the footprint preferably is in the range of 3×3 to 100×100 mm, preferably of 5×5 to 80×80 mm.

In a further preferred embodiment, the component is selected from the group of the Quad Flat Packages (QFP), for example Bumpered Quad Flat Package with heat distributor (BQFPH) and heat-sinked Quad Flat Package (HQFP).

A substrate provided with a solder deposit is provided in a second step. The substrate on which the component is mounted by means of the method according to the present invention comprises a second surface by means of which the contacting to the component takes place. Preferably, the second surface of the substrate comprises at least one metal selected from the group consisting of nickel, copper, gold, silver, aluminum, tin, and palladium as well as alloys of two or more of the metals.

Preferably, the substrate is a metallized substrate, i.e. a substrate comprising at least one metal surface. In this context, the base body of the substrate can consist of ceramics, paper, epoxy resin or pure copper.

The method according to the present invention is particularly well-suited for processes, in which the application of the solder deposit and the mechanical contacting of the component to the solder deposit take place in automated manner. To enable rapid and precise working technique, it is desirable for the application of the solder deposit to take place rapidly and without additional working steps. Therefore, an embodiment of the method, in which the application of the solder deposit takes place by means of screen printing, doctor coating, stencil printing, dispensing or jetting, is preferred This renders the application precise, which permits the production of small integrated circuit as well. In this context, the solder deposit is 25 to 200 μm, preferably 30 to 150 μm, for example 50 to 150 μm or 80 to 150 μm, in thickness. Alternatively, the solder deposit can just as well be 25 to 130 μm, in particular 30 to 120 μm or 30 to 100 μm in thickness. As a result, optimal thermal bonding of the component to the substrate and thus optimal cooling of the component are ensured. Likewise, the spreading of the selected solder paste in this range of thickness can be reduced and/or prevented.

In a next step of the method according to the present invention, the first surface of the component is mechanically contacted to the second surface of the substrate by means of the solder deposit.

Subsequently, the solder paste is heated beyond the liquidus temperature of the solder such that a connection between component and substrate by means of the solder paste is formed. In this context, the solder paste is preferably heated appropriately such that the solder transitions into its liquidus phase, but without the solder paste, component and/or substrate getting damaged. Preferably, the solder is heated to a temperature 5 to 60° C., preferably 10 to 50° C. above the liquidus temperature of the solder. The heating preferably takes place by means of a heating plate onto which the substrate is placed such that the surface of the substrate opposite from the second surface contacts the heating plate. Alternatively, the solder can just as well be heated by means of heated molded parts, bracket, stamp, infrared radiator, laser beams or by means of steam.

The components mounted to the substrate according to the method according to the present invention show a significantly reduced incidence of short-circuits.

Therefore, a further subject matter of the present invention is a component that is mounted on a substrate and can be or is obtained according to the method according to the present invention.

The present invention shall be described in more detail by means of the following examples, which are in no way to be understood as to be limiting the inventive concept.

### Examples

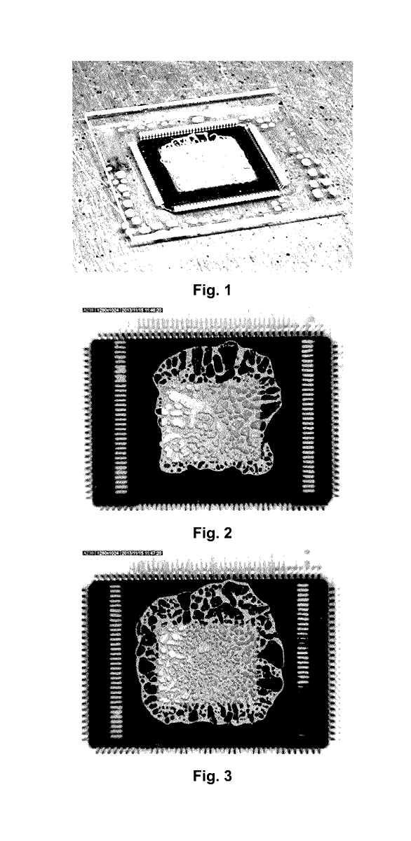

The components produced by means of the method according to the present invention were assessed at different solder deposit thickness by means of the Anti-Capillary test (AC test). For this purpose, the solder paste was applied to the thermal connecting site of a QFP component (for example from Infineon Technologies AG, Germany) and covered with a glass plate. The QFP component was placed, by the opposite surface, on a heating plate at a temperature of 200° C. such that the behavior of the paste could be assessed. The experimental set-up is shown in FIG. 1.

The results obtained were rated by means of scores, whereby a score of 1 represented very good results and a score of 2 represented good results, in which there were no short-circuits due to undesired contact of the solder paste with the electrical contacting sites of the component. A score of 3 was assigned to tests, in which the solder paste spread to the extent that it contacted the electrical connecting sites of the component. The results are summarized in Table 2, whereby each of the tests was performed with a solder paste 1, which was to be used according to the present invention, and a conventional reference solder paste 2.

Table 1 shows the formula of the solder paste used in the AC tests, whereby solder paste 1 describes a solder paste, which was to be used according to the present invention, whereas solder paste 2 describes a solder paste that comprises only one dicarboxylic acid.

TABLE 1

| | Solder paste | |
|---|---|---|
| | Solder paste 1 | Solder paste 2 |
| | Flux | |
| | Amount, in % | Amount, in % |
| | by weight | by weight |
| Adipic acid | 10.0 | 10.0 |
| Oxalic acid | 0.7 | — |
| Bis-C₈-dialkylamine | 2.1 | 2.1 |
| N,N-Dialkyl fatty amine | 2.1 | 2.1 |
| Hydrogenated colophony | 45.3 | 45.3 |
| Triethanolamine•HBr | 1.5 | 1.5 |
| Castor oil | 2.7 | 2.7 |
| Tri-Propyleneglycol-n-butylether | 35.6 | 36.3 |
| Flux (total) | 100.0 | 100.0 |
| | Paste | |
| | Amount, in % | Amount, in % |
| | by weight | by weight |
| Solder (SnAgCu) | 89.25 | 89.25 |
| Flux | up to 100.0 | up to 100 |

TABLE 2

| | Solder paste 1 | Solder paste 2 |
|---|---|---|
| Thick solder deposit | (Result of the AC test) | (Result of the AC test) |
| 100 μm | 1 | 3 |
| 120 μm | 1 | 3 |
| 160 μm | 2 | 3 |
| 240 μm | 3 | 3 |

As is evident from Table 2, the solder paste according to the present invention shows very good to good results in the AC test, whereas the use of the conventional reference solder paste 2 was associated with excessive spreading of the solder paste and therefore with poor results in the AC test.

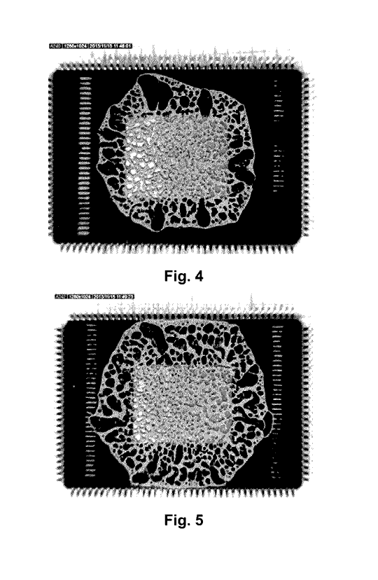

FIGS. 2 to 5 show the results of the AC tests on solder paste 1, which is to be used according to the present invention, in which the solder deposit was applied at varying thickness, as is shown in Table 2. As is evident from the figures, the results of the experiments, in which the thickness of the solder deposit was in the range between 100 and 160 μm, evidenced very good to good test results (FIG. 2: Measurement on solder paste 1 at 100 μm; FIG. 3: Measurement on solder paste 1 at 120 μm; FIG. 4: Measurement on solder paste 1 at 160 μm). Although the solder paste has spread relatively extensively at a solder deposit thickness of 160 μm (FIG. 4), there is no undesired contact with the electrical connecting sites of the component such that it was possible to prevent short-circuits. In contrast, a layer thickness outside the inventive range of 25 to 200 μm gave rise to contacts of the solder paste with the electrical connecting sites of the component and ensuing short-circuiting (FIG. 5).

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

16. A method for mounting a quad flat package (QFP) component on a substrate, the method comprising the following steps:
i) providing a QFP component having a first surface;
ii) providing a substrate having a second surface that is provided with a solder deposit, the solder deposit being formed by a solder paste comprising:
a) 5 to 15% by weight of a flux and
b) 85 to 95% by weight of a solder, wherein weight specifications each relate to a total weight of the solder paste;
iii) mechanically contacting the first surface of the QFP component to the second surface of the substrate by the solder deposit, the thickness of the solder deposit being in a range of 25 to 200 μm; and
iv) heating the solder deposit beyond a liquidus temperature of the solder, wherein the flux comprises:
a) 7 to 13% by weight adipic acid;
b) 0.3 to 2.0% by weight oxalic acid; and
c) an amine, selected from amine component X and amine component Y, wherein amine component X is a diamine with tertiary amino groups and amine component Y is a diamine or polyamine, in which at least 2 of the amino groups are separated from each other by at least 3 carbon atoms and which comprise at least 4 carbon atoms; and
wherein weight specifications of the dicarboxylic acids each relate to a total weight of the flux.

17. The method according to claim 16, wherein the amine component X is selected from the group consisting of 1,2-tetramethylethylenediamine, 1,2-tetraethylethylenediamine, 1,2-tetrapropylethylenediamine, and 1,2-tetra-isopropylethylenediamine.

18. The method according to claim 16, wherein the amine component Y is selected from the group consisting of N-coco-1,3-diaminopropane, 1,6-diaminohexane, 1,7-diaminoheptane, 1,8-diaminooctane, 1,9-diaminononane, and 1,10-diaminodecane.

19. The method according to claim 16, wherein the solder is a tin-based solder.

20. The method according to claim 16, wherein the solder comprises silver in an amount of 0.1 to 8.0% by weight relative to the total weight of the solder.

21. The method according to claim 16, wherein the solder comprises copper in an amount of 0.1 to 1.5% by weight relative to the total weight of the solder.

22. The method according to claim 16, wherein the liquidus temperature of the solder is in the range of 200 to 250° C.

23. The method according to claim 16, wherein the first surface of the QFP component comprises at least one metal selected from the group consisting of copper, silver, gold, nickel, aluminium, tin, palladium and alloys of two or more of the metals.

24. The method according to claim 16, wherein the second surface of the substrate comprises at least one material selected from the group consisting of nickel, gold, copper, tin, silver, aluminium, palladium and alloys of two or more of the metals.
